(19) United States
(12) Patent Application Publication
(10) Pub. No.: US 2009/0007956 A1
(43) Pub. Date: Jan. 8, 2009

(54) DISTRIBUTED COAX PHOTOVOLTAIC DEVICE

(75) Inventors: Krzysztof Kempa, Chestnut Hill, MA (US); Michael Naughton, Norwood, MA (US)

Correspondence Address: FOLEY AND LARDNER LLP;SUITE 500, 3000 K STREET NW, WASHINGTON, DC, 20007, US

(73) Assignee: Solasta, Inc.

(21) Appl. No.: 12/166,920

(22) Filed: Jul. 2, 2008

Related U.S. Application Data
(60) Provisional application No. 60/929,578, filed on Jul. 3, 2007.

(51) Int. Cl. H01L 31/042

(52) U.S. Cl. 136/244

(57) ABSTRACT

A photovoltaic device includes a plurality of photovoltaic cells. Each photovoltaic cell of the plurality of photovoltaic cells includes a first electrode, a second electrode which is shared with at least one adjacent photovoltaic cell, and a photovoltaic material located between and in electrical contact with the first and the second electrodes. A thickness of the second electrode in a direction from one photovoltaic cell to an adjacent photovoltaic cell is less than an optical skin depth of the second electrode material, and a separation between first electrodes of adjacent photovoltaic cells is less than a peak wavelength of incident radiation.

### CROSS-REFERENCE TO RELATED PATENT APPLICATIONS

The present application claims benefit of U.S. provisional application 60/929,578, filed Jul. 3, 2007, which is incorporated herein by reference in its entirety.

### BACKGROUND

The present invention relates generally to the field of photovoltaic or solar cells and more specifically to photovoltaic cells containing photovoltaic material which contains multiple band gaps or which exhibits the multiple exciton effect.

U.S. Published Application 2004/0118451 describes a bulk multijunction PV device with an increased efficiency. The PV device comprises two or more p-n junction cells in semiconductor materials. The multijunction cells may be made of GaInP/GaAs/Ge materials having band gaps of 1.85/1.43/0.7 eV, respectively. Alternatively, each cell may comprise a p-n junction in InGaN material having a different ratio of In to Ga in each cell which provides a different band gap for each cell.

### SUMMARY

An embodiment of the present invention provides a photovoltaic device including a plurality of photovoltaic cells. Each photovoltaic cell of the plurality of photovoltaic cells includes a first electrode, a second electrode which is shared with at least one adjacent photovoltaic cell, and a photovoltaic material located between and in electrical contact with the first and the second electrodes. A thickness of the second electrode in a direction from one photovoltaic cell to an adjacent photovoltaic cell is less than an optical skin depth of the second electrode material, and a separation between first electrodes of adjacent photovoltaic cells is less than a peak wavelength of incident radiation.

### BRIEF DESCRIPTION OF THE DRAWINGS

FIG. 1 is a schematic three dimensional view of a PV cell according to an embodiment of the invention.

FIGS. 2A and 2D-2G are schematic side cross sectional views of PV devices according to embodiments of the invention. FIG. 2B is a scanning microscopy image of a plurality of nanorods formed on an optically transmissive substrate. FIG. 2C is a photograph showing that the substrate covered with the plurality of nanorods is optically transmissive, such as optically transparent, and that an underlying webpage on a computer terminal is visible through the substrate.

FIG. 3A is a schematic top view of a multichamber apparatus for forming the PV device according to an embodiment of the invention.

FIGS. 3B-3F are side cross sectional views of steps in a method of forming the PV device in the apparatus of FIG. 3A.

### DETAILED DESCRIPTION OF THE EMBODIMENTS

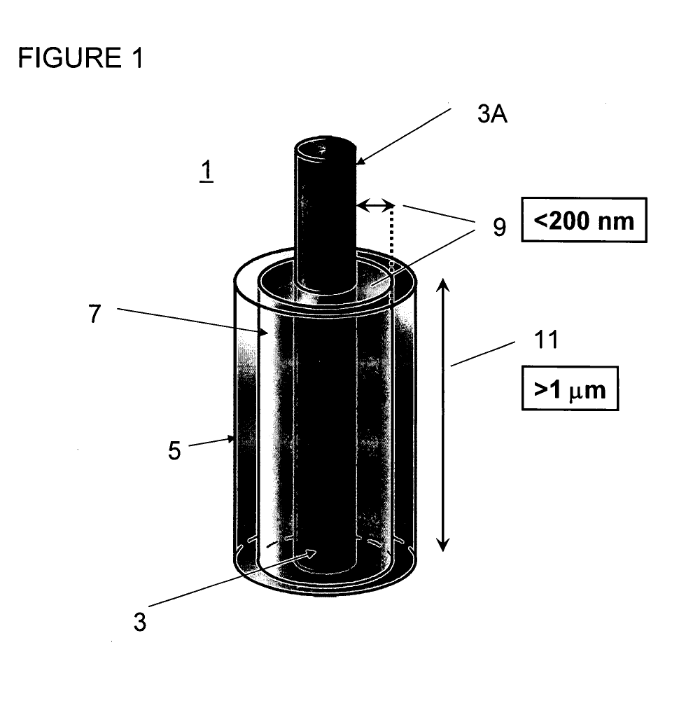

FIG. 1 illustrates a photovoltaic cell 1 according to an embodiment of the invention. The cell 1 contains a first or inner electrode 3, a second or outer electrode 5, and a photovoltaic (PV) material 7 located between and in electrical contact with the first and the second electrodes. The width 9 of the photovoltaic material in a direction from the first electrode 3 to the second electrode 5 (i.e., left to right in FIG. 1) is less than about 200 nm, such as 100 nm or less, preferably between 10 and 20 nm. The height 11 of the photovoltaic material (i.e., in the vertical direction in FIG. 1) in a direction substantially perpendicular to the width of the photovoltaic material is at least 1 micron, such as 2 to 30 microns, for example 10 microns. The term “substantially perpendicular” includes the exactly perpendicular direction for hollow cylinder shaped PV material 7, as well as directions which deviate from perpendicular by 1 to 45 degrees for a hollow conical shaped PV material which has a wider or narrower base than top. Other suitable PV material dimensions may be used.

The width 9 of the PV material 7 preferably extends in a direction substantially perpendicular to incident solar radiation that will be incident on the PV cell 1. In FIG. 1, the incident solar radiation (i.e., sunlight) is intended to strike the PV material 7 at an angle of about 70 to 110 degrees, such as 85 to 95 degrees, with respect to the horizontal width 9 direction. The width 9 is preferably sufficiently thin to substantially prevent phonon generation during photogenerated charge carrier flight time in the photovoltaic material to the electrode(s). In other words, the PV material 7 width 9 must be thin enough to transport enough charge carriers to the electrode(s) 3 and/or 5 before a significant number of phonons are generated. Thus, when the incident photons of the incident solar radiation are absorbed by the PV material and are converted to charge carriers (electrons/holes or excitons), the charge carriers should reach the respective electrode(s) 3, 5 before a significant amount of phonons are generated (which convert the incident radiation to heat instead of electrical charge carriers which provide a photogenerated electrical current). For example, it is preferred that at least 40%, such as 40-100% of the incident photons are converted to a photogenerated charge carriers which reach a respective electrode and create a photogenerated electrical current instead of generating phonons (i.e., heat). A width 9 of about 10 nm to about 20 nm for the example shown in FIG. 1 is presumed to be small enough to prevent generation of a significant number of phonons.

The height 11 of the photovoltaic material 7 is preferably sufficiently thick to convert at least 90%, such as 90-100% of incident photons in the incident solar radiation to charge carriers. Thus, the height 11 of the PV material 7 must be sufficiently thick to collect all the solar radiation. Preferably, but not necessarily, the height 11 is at least 10 times greater, such as at least 100 times greater, such as 1,000 to 10,000 times greater than the width 9.

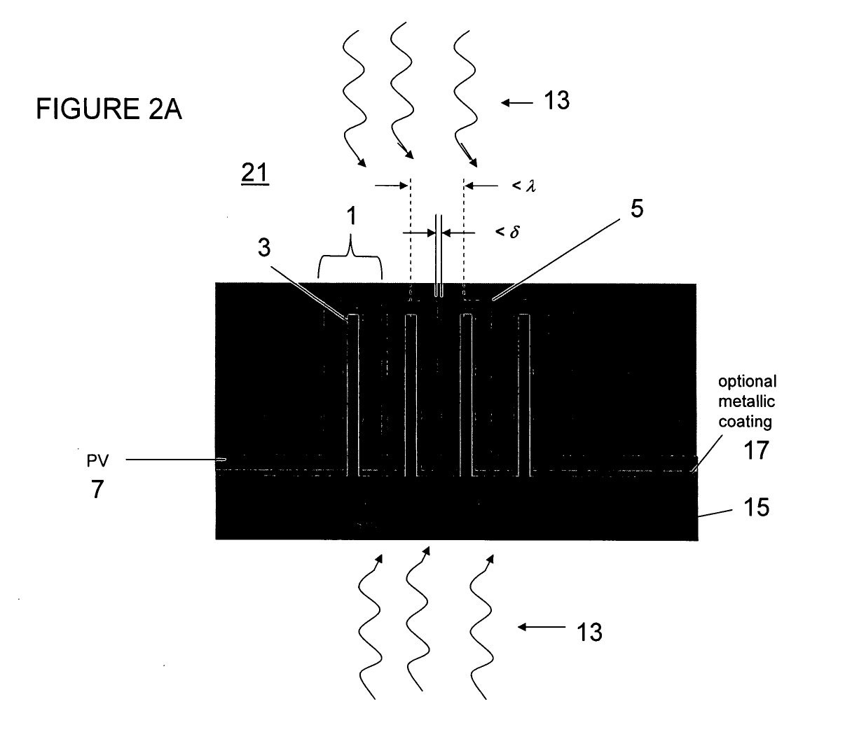

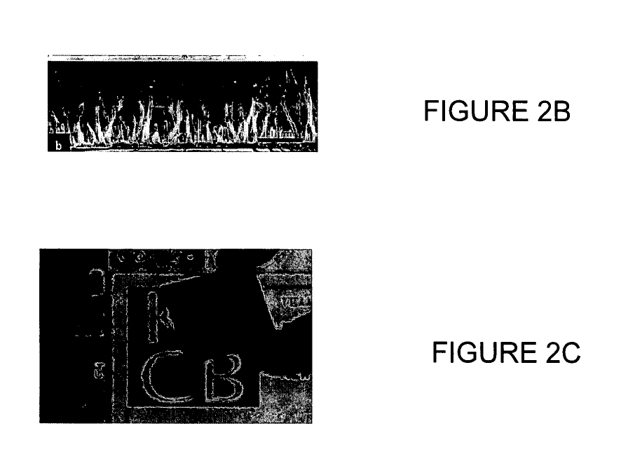

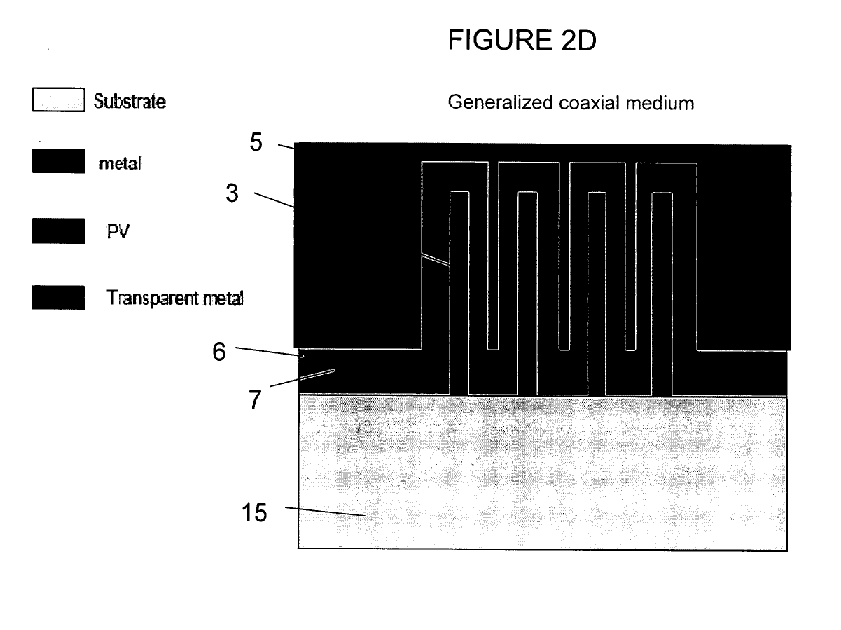

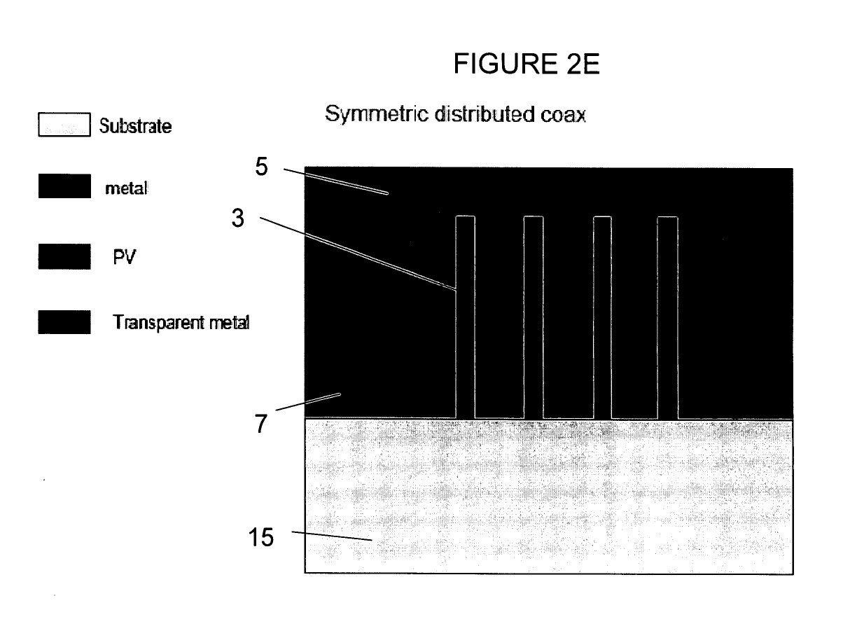

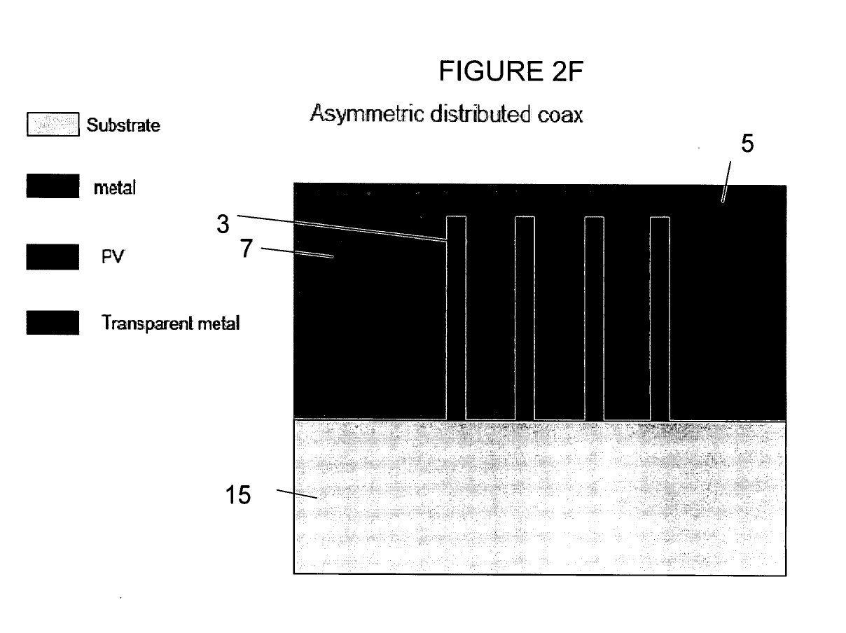

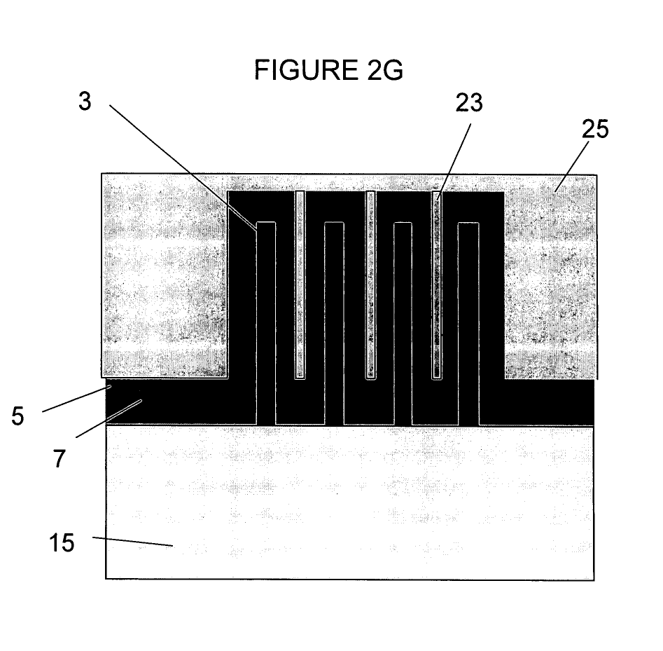

The first electrode 3 preferably comprises an electrically conducting nanorod, such as a nanofiber, nanotube or nanowire. For example, the first electrode 3 may comprise an electrically conductive carbon nanotube, such as a metallic multi walled carbon nanotube, or an elemental or alloy metal nanowire, such as molybdenum, copper, nickel, gold, or palladium nanowire, or a nanofiber comprising a nanoscale rope of carbon fibrous material having graphitic sections. The nanorod may have a cylindrical shape with a diameter of 2 to 200 nm, such as 30 to 150 nm, for example 50 nm, and a height of 1 to 100 microns, such as 10 to 30 microns. If desired, the first electrode 3 may also be formed from a conductive polymer material. Alternatively, the nanorod may comprise an electrically insulating material which is covered by an electrically conductive shell to form the electrode 3. For example, as will be described in more detail below with respect to FIG. 2A, an electrically conductive layer may be formed over a substrate such that it forms a conductive shell around the nanorod to form the electrode 3.

The photovoltaic material 7 surrounds at least a lower portion of the nanorod electrode 3, as shown in FIG. 1. The photovoltaic material 7 may comprise any one or more of semiconductor nanocrystals, a bulk inorganic semiconductor material, such as amorphous or nanocrystalline silicon or a compound semiconductor material, such as a III-V material, a polymer photoactive material, an organic molecular photoactive material or a biological photoactive material.

For example, the photovoltaic material 7 may comprise semiconductor nanocrystals (also known as quantum dots), such as silicon nanocrystals. Alternatively, the nanocrystals may have band gap that is significantly smaller than peak solar radiation energy to exhibit the multiple exciton effect (also known as the carrier multiplication effect) in response to irradiation by solar radiation. Such nanocrystals may have a band gap which is equal to or less than 0.8 eV, such as 0.1 to 0.8 eV (i.e., at least 2.9 times smaller than the 2.34 eV peak energy of solar radiation). Examples of such nanocrystal materials include inorganic semiconductors, such as Ge, SiGe, PbSe, PbTe, SnTe, SnSe, Bi₂Te₃, Sb₂Te₃, PbS, Bi₂Se₃, InAs, or InSb, as well as ternary and quaternary combinations thereof

Preferably, the nanocrystals have an average diameter of 10 to 100 nm, such as 20 to 30 nm. The nanocrystals may be sufficiently large such that their band gap is determined by their material composition rather than their size (i.e., the band gap is the property of the material rather than size). The nanocrystals may comprise two sets of different nanocrystal material compositions.

The nanocrystals are in physical or tunneling contact with each other to provide a path for charge carriers from the inner electrode 3 to the outer electrode 5. The PV material 7 may comprise nanocrystals encapsulated in an optically transparent matrix material, such as an optically transparent polymer matrix (for example EVA or other polymer encapsulating materials used in solar cells) or optically transparent inorganic oxide matrix material, such as glass, silicon oxide, etc. Small distance between the nanocrystals in the matrix assures carrier tunneling in absence of direct carrier transport between adjacent nanocrystals. Alternatively, the matrix may be omitted and the nanocrystals may comprise a densely packed nanocrystal body.

Alternatively, the PV material may include other PV active materials, such as bulk inorganic semiconductor layers, such as amorphous or nanocrystalline silicon or compound semiconductor materials, photoactive polymers (such as semiconducting polymers), organic photoactive molecular materials, such as dyes, or a biological photoactive materials, such as biological semiconductor materials. Photoactive means the ability to generate charge carriers (i.e., a current) in response to irradiation by solar radiation. Organic and polymeric materials include polyphenylene vinylene, copper phthalocyanine (a blue or green organic pigment) or carbon fullerenes. Biological materials include proteins, rhodonines, or DNA (e.g. deoxyguanosine, disclosed in Appl. Phys. Lett. 78, 3541 (2001) incorporated herein by reference). The PV material 7 may also comprise a combination of nanocrystal and bulk semiconductor layers. For example, the PV material may comprise a three-layer film containing: i) a bulk semiconductor layer (such as heavily doped, p-type amorphous or polycrystalline silicon layer), ii) a semiconductor nanocrystal layer (such as intrinsic silicon or other nanocrystal film); and iii) a bulk semiconductor layer (such as heavily doped, n-type amorphous or polycrystalline silicon layer) to form a p-i-n type PV cell with the nanocrystal intrinsic layer located between the bulk p and n-type layers. These layers are arranged in order from the inner electrode 3 to the outer electrode 5. The nanocrystal layer may comprise silicon nanocrystals made by the layer-by-layer method or other methods (see for example, N. Malikova, et al., Langmuir 18 (9) (2002) 3694, incorporated herein by reference, for a general description of the layer-by-layer method). This configuration provides a maximum internal electric field of about 1V (Si gap), and will reduce or eliminate short circuits. The bulk silicon layers may be about 5-10 nm thick and the nanocrystal layer may be about 20-30 nm thick. It should be noted that the bulk/nanocrystal/bulk p-i-n PV cell may have configurations other than the coax configurations shown in FIGS. 1 and 2 and may be positioned horizontally instead of vertically. Furthermore, bulk semiconductor materials other than silicon may also be used.

The PV material 7 may consist entirely of semiconductor material of one conductivity type. This forms a Schottky junction type PV cell 1. In an alternative configuration, a p-n or p-i-n type PV cell 1 is formed. In the p-n or p-i-n type PV cell, the PV material contains a p-n or p-i-n junction. For example, the PV material 7 may comprise intrinsic semiconductor material which is located between semiconductor thin films of opposite conductivity type to form the p-i-n type PV cell. In the p-i-n PV cell, a first p or n type semiconductor thin film is formed around the inner electrode 3. Then, a nanocrystal or bulk semiconductor containing intrinsic region is formed around the first semiconductor thin film. Then, a second n or p type semiconductor thin film of the opposite conductivity type to the first semiconductor thin film is formed around the nanocrystal intrinsic region. Each semiconductor thin film may have a thickness of about 5 to about 20 nm.

The second electrode 5 surrounds the photovoltaic material 7 to form a so-called nanocoax shown in FIG. 1. The electrode 5 may comprise any suitable conductive material, such as a conductive polymer or an elemental metal or a metal alloy, such as copper, nickel, aluminum or their alloys. Alternatively, the electrode 5 may comprise an optically transmissive and electrically conductive material, such as a transparent conductive oxide (TCO), such as indium tin oxide or aluminum zinc oxide.

Optionally, an upper portion of the nanorod 3 extends above the top of photovoltaic material 7 and forms an optical antenna 3A for the photovoltaic cell 1. However, the antenna is preferably omitted, as will be described in more detail below with respect to FIG. 2A. The term “top” means the side of the PV material 7 distal from the substrate upon which the PV cell is formed. Thus, the nanorod electrode 3 height may be the same as or greater than the height 11 of the PV material 7. If the antenna 3A is present, then the height of the antenna 3A may be greater than three times the diameter of the nanorod 3. The height of the antenna 3A may be matched to the incident solar radiation and may comprise an integral multiple of ½ of the peak wavelength of the incident solar radiation (i.e., antenna height=(n/2)×530 nm, where n is an integer).

In an alternative embodiment, the antenna 3A is supplemented by or replaced by a nanohorn light collector. In this embodiment, the outer electrode 5 extends above the PV material 7 height 11 and is shaped roughly as an upside down cone for collecting the solar radiation.

In another alternative embodiment, the PV cell 1 has a shape other than a nanocoax. For example, the PV material 7 and/or the outer electrode 5 may extend only a part of the way around the inner electrode 3. Furthermore, the electrodes 3 and 5 may comprise plate shaped electrodes and the PV material 7 may comprise thin and tall plate shaped material between the electrodes 3 and 5.

FIG. 2A illustrates a PV device 21 containing a plurality of PV cells 1, such as an array of PV cells 1. While only four cells 1 are illustrated for clarity, it should be understood that the device 21 may contain significantly more than four cells. In the device 21, a thickness of the second electrode 5 in a direction from one photovoltaic cell 1 to an adjacent photovoltaic cell 1 (i.e., left to right in FIG. 2A) is less than an optical skin depth of the second electrode material while a separation between first electrodes 3 of adjacent photovoltaic cells 1 is less than a peak wavelength of incident radiation, such as less than a peak wavelength (i.e., about 550 nm) of the incident solar radiation.

As shown in FIG. 2A, each photovoltaic cell 1 comprises a nanocoax whose axis is oriented perpendicular to a substrate 15 of the photovoltaic device 21. The second electrode 5 of each photovoltaic cell comprises a common electrode which fills a space between the photovoltaic cells 1 and which electrically contacts the photovoltaic material 7 of each photovoltaic cell.

In one embodiment of the invention shown in FIG. 2A, the PV device 21 includes a continuous photovoltaic material layer 7 which forms the photovoltaic material in each photovoltaic cell and which is located over the substrate in a space between adjacent photovoltaic cells. The common electrode 5 fills a space above the photovoltaic material layer 7 between adjacent photovoltaic cells 1. Electrode 5 electrically contacts the photovoltaic material layer 7. Thus, as shown in FIG. 2A, the thickness of the common electrode 5 (serving as the outer electrodes of each cell 1) between the nanocoax cells 1 is less than the optical skin depth, delta, into the electrode material, and the center-to-center separation between neighboring coax cells is less than the incident solar radiation (or other radiation type) wavelength, lambda. This device 21 can be viewed as a multi-core coax which also transmits in the transverse electromagnetic mode and/or as an extremely dense nanocoaxial medium, where the inter-coax conductor is thinner than the skin depth.

In one embodiment of the invention, the optical skin depth, delta, of the second electrode material is less than a peak wavelength, lambda, of the incident radiation. In this embodiment, shown in FIG. 2D, the second electrode 5 may comprise an opaque metal or metal alloy which is not transmissive to solar radiation, such as aluminum, copper or their alloys. For example, the optical skin depth of such second electrode material is about 10 nm to about 20 nm. If the common electrode 5 is not optically transmissive and the PV material 7 is not exposed above the common electrode 5, then the device 21 is formed on an optically transmissive substrate 15, such as glass, quartz, plastic, etc. The substrate 15 side of the device 21 is positioned toward the radiation source, such as the Sun, and the radiation 13 is incident on the PV material 7 through the substrate 15. Optionally, an optically transmissive, electrically conductive layer 6 may be formed between the PV material 7 and the common electrode 5 to reduce the undesired reflection. The conductive layer 6 may comprise a metal oxide layer, for example ITO or AZO, or a very thin metal or metal alloy layer, such as a 5-15 nm thick Cr or Ti layer. However, layer 6 may be omitted if desired. Likewise, layer 6 may be added to the device 21 shown in FIG. 2A containing an optically transmissive common electrode 5.

If the substrate 15 is not electrically conductive, then an optional conductive layer 17 is located between the substrate 15 and the photovoltaic material layer 7 in a space between adjacent photovoltaic cells 1, as shown in FIG. 2A. The conductive layer 17 contacts each nanorod electrode 3 and acts as an electrical contact and output for each nanorod 3 electrode. The conductive layer 17 may be optically transmissive and may comprise a thin copper or copper alloy layer or a conductive transparent oxide such as ITO or AZO. Otherwise, the conductive layer 17 may comprise an optically non-transmissive metal or metal alloy layer, such as chromium or titanium layer, having a thickness of 100 to 500 nm, such as 200 to 300 nm.

If desired, the nanorod may be formed directly on the conductive layer 17 or the nanorod may be formed on the substrate 15 surface and the conductive layer 17 surrounds the nanorods. If the nanorods themselves are not electrically conductive, then the conductive layer 17 is also located between each nanorod and the photovoltaic material layer in each photovoltaic cell to form a conductive shell portion of the electrode 3 around each insulating nanorod core as shown in FIG. 2A.

In another embodiment, the optical skin depth, delta, of the second electrode 5 material is greater than a peak wavelength, lambda, of the incident radiation. In this case, the second electrode comprises an optically transmissive, electrically conductive metal oxide, such as ITO or AZO. The optical skin depth of the second electrode material may be greater than 700 nm. In this embodiment, the device 21 may be formed on an optically non-transmissive substrate 15 (i.e., opaque substrate). Preferably, but not necessarily, the substrate 15 material is electrically conductive. For example the substrate 15 comprises a metal, such as an aluminum or stainless steel or other metal substrate. The conductive substrate 15 electrically contacts the electrodes 3 and acts as a common electrical contact for the electrodes 3. In this case, the conductive layer 17 may be omitted as shown in FIG. 2E to form a so-called “symmetric distributed coax”. However, if desired, the conductive layer 17 may also be added to the device 21 of this embodiment if desired. In this configuration, the device 21 is position with the second electrode 5 side toward the radiation source, such as the Sun, and the radiation 13 is incident on the PV material 7 from the side opposite to the substrate 15 side. If desired, the PV material 7 may fill the entire space between the nanorod electrodes 3 and the transparent electrode 5 may be located above the PV material 7 and electrodes 3, as shown in FIG. 2F, to form a so-called “asymmetric distributed coax”. In an alternative configuration shown in FIG. 2G, the common electrode 5, such as the optically transmissive common electrode 5 does not fill the entire space between the PV cells 1. In this configuration, the common electrode contains grooves 23 between adjacent cells 1. The width of the grooves 23 (in the left to right direction in FIG. 2G) may range between 0.001 to 1 microns. The grooves 23 may be filled with an optically transmissive insulating filler material 25, such as glass, polymer, etc. Of course if desired, the grooves may be omitted, as shown in FIG. 2A.

If desired, one or more insulating, optically transparent encapsulating and/or antireflective layers may be formed over the cells 1. The encapsulating layer(s) may comprise a transparent polymer layer, such as EVA or other polymers generally used as encapsulating layers in PV devices, and/or an inorganic layer, such as silicon oxide or other glass layers.

Without wishing to be bound by a particular theory and as noted above, if the device 21 is viewed as a multi-core coax which acts as a transverse electromagnetic mode transmission line, then coupling to external radiation should be significantly easier than via a single-core coax. Without wishing to be bound by a particular theory, it is believed that the multi-core coax provides an effect which is similar to the parasitic antenna effect. FIGS. 2B and 2C provides experimental support for this non-limiting theory. In spite of subwavelength separation between optically-thick nanorods (carbon nanotubes) shown in FIG. 2B, the transmission of light through these nanorods is very high, as shown in FIG. 2C, where a webpage on a computer terminal is visible through the nanorods. The high transmission means that the light gets into the medium, where it can be captured by the PV material when the PV material is deposited around the nanotubes. Thus, the antennas 3A may be omitted from the device 21 and opaque, metallic substrates 15 may be used because the solar radiation may be incident on the top of the device 21.

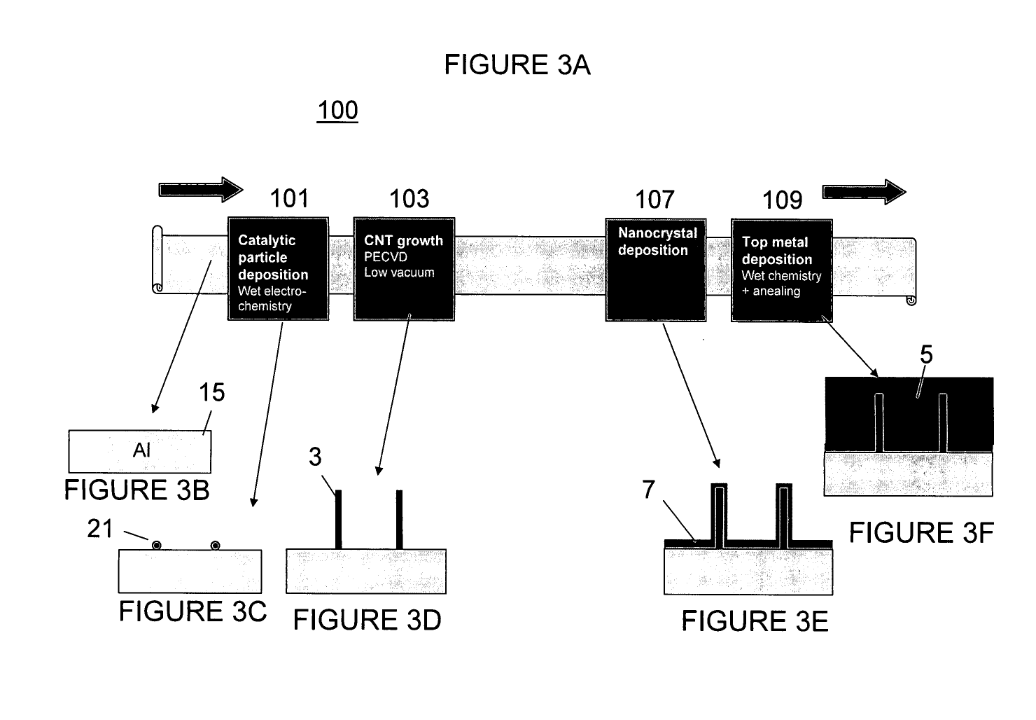

FIG. 3A illustrates a multichamber apparatus 100 for making the PV cells and FIGS. 3B-3F illustrate the steps in a method of making the PV cells 1 according to one embodiment of the invention. As shown in FIGS. 3A and 3B, the PV cells 1 may be formed on a moving conductive substrate 15, such as on an continuous aluminum or steel web or strip which is spooled (i.e., unrolled) from one spool or reel and is taken up onto a take up spool or reel. The substrate 15 passes through several deposition stations or chambers in a multichamber deposition apparatus. Alternatively, a stationary, discreet substrate (i.e., a rectangular substrate that is not a continuous web or strip) may be used. Electrically insulating substrates may also be used.

First, as shown in FIG. 3C, nanorod catalyst particles 21, such as iron, cobalt, gold or other metal nanoparticles are deposited on the substrate 15 in chamber or station 101. The catalyst particles may be deposited by wet electrochemistry or by any other known metal catalyst particle deposition method. The catalyst metal and particle size are selected based on the type of nanorod electrode 3 (i.e., carbon nanotube, nanowire, etc.) that will be formed.

In a second step shown in FIG. 3D, the nanorod electrodes 3 are selectively grown in chamber or station 103 at the nanoparticle catalyst sites by tip or base growth, depending on the catalyst particle and nanorod type. For example, carbon nanotube nanorods may be grown by PECVD in a low vacuum, while metal nanowires may be grown by MOCVD. The nanorod electrodes 3 are formed perpendicular to the substrate 15 surface.

In a third step shown in FIG. 3E, the PV material 7 is formed over and around the nanorod electrodes 3 in chamber or station 107. Several different methods may be used to deposit the PV material 7.

One method of forming the PV material comprises depositing a continuous semiconductor film, such as a Si, Ge or PbSe film, having a width 9 less than 20 nm using any suitable vapor deposition technique around nanorod shaped inner electrodes 3. Due to the nanoscale surface curvature of the nanorods 3, the film may contain nanocrystals or quantum dots.

Another method of forming the PV material comprises providing prefabricated semiconductor nanocrystals by separately forming or obtaining commercial semiconductor nanocrystals. The semiconductor nanocrystals are then attached to at least a lower portion of a nanorod shaped inner electrodes 3 to form the photovoltaic material comprised of nanocrystals. For example, the nanocrystals may be provided from a nanocrystal solution or suspension over the substrate 15 and over the electrodes 3. If desired, the nanorod electrodes 3, such as carbon nanotubes, may be chemically functionalized with moieties, such as reactive groups which bind to the nanocrystals using van der Waals attraction or covalent bonding.

Another method of forming the PV material comprises providing prefabricated nanocrystals and placing the semiconductor nanocrystals in an optically transparent polymer matrix, such as an EVA or other matrix. The polymer matrix containing the semiconductor nanocrystals is then deposited over the substrate 15 and around the nanorod shaped inner electrodes 3 to form a composite photovoltaic material comprised of nanocrystals in the polymer matrix.

Another method of forming the PV material comprises depositing a first transparent oxide layer, such as a glass layer, over the substrate 15 and around a lower portion of nanorod shaped inner electrodes 3. The glass layer may be deposited by sputtering, CVD or spin-on coating. This is followed by depositing the semiconductor nanocrystals over the transparent oxide. The nanocrystals may be formed in-situ by CVD on the transparent oxide, or prefabricated nanocrystals may be deposited on the oxide from a solution or suspension. Then, a second transparent oxide layer is deposited over the deposited semiconductor nanocrystals to form a composite PV material comprised of nanocrystals in a transparent oxide matrix. The above deposition steps may be repeated several times until a desired thickness is achieved.

In a fourth step shown in FIG. 3F, the outer electrode 5 is formed around the photovoltaic material 7 in chamber or station 109. The outer electrode 5 may be formed by a wet chemistry method, such as by Ni or Cu electroless plating or electroplating following by an annealing step. Alternatively, if the electrode 5 comprises a transparent conductive oxide, then it may be formed by PVD, such as sputtering or evaporation. The outer electrode 5 and the PV material 7 may be polished by chemical mechanical polishing and/or selectively etched back to planarize the upper surface of the PV cells 1 and to expose the upper portions of the nanorods 3 and/or the PV material 7.

A method of operating the device 21 containing the PV cells 1 includes exposing the cells 1 to incident solar radiation 13 propagating in one direction from the top or bottom, as shown in FIG. 2A, and generating a current from the PV cells in response to the step of exposing. For example, the nanocrystal PV material may exhibit the multiple exciton effect, which is a subset of the carrier multiplication effect. As discussed above, the width 9 of the PV material 7 between the inner 3 and the outer 5 electrodes in a direction substantially perpendicular to the radiation 13 direction is sufficiently thin to substantially prevent phonon generation during photogenerated charge carrier flight time in the photovoltaic material to at least one of the electrodes. The height 11 of the PV material 7 in a direction substantially parallel to the radiation 13 direction is sufficiently thick to convert at least 90%, such as 90-100% of incident photons in the incident solar radiation to charge carriers, such as excitons.

The foregoing description of the invention has been presented for purposes of illustration and description. It is not intended to be exhaustive or to limit the invention to the precise form disclosed, and modifications and variations are possible in light of the above teachings or may be acquired from practice of the invention. The description was chosen in order to explain the principles of the invention and its practical application. It is intended that the scope of the invention be defined by the claims appended hereto, and their equivalents.

1. A photovoltaic device, comprising a plurality of photovoltaic cells, wherein:
each photovoltaic cell of the plurality of photovoltaic cells comprises:
a first electrode;
a second electrode which is shared with at least one adjacent photovoltaic cell; and
a photovoltaic material located between and in electrical contact with the first and the second electrodes,
a thickness of the second electrode in a direction from one photovoltaic cell to an adjacent photovoltaic cell is less than an optical skin depth of the second electrode material; and
a separation between first electrodes of adjacent photovoltaic cells is less than a peak wavelength of incident radiation.

2. The device of claim 1, wherein a width of the photovoltaic material in a direction from the first electrode to the second electrode is less than about 200 nm, and a height of the photovoltaic material in a direction substantially perpendicular to the width of the photovoltaic material is at least 1 micron.

3. The device of claim 2, wherein the width of the photovoltaic material in a direction substantially perpendicular to an intended direction of incident solar radiation is sufficiently thin to substantially prevent phonon generation during photogenerated charge carrier flight time in the photovoltaic material to at least one of the first and to the second electrodes, and the height of the photovoltaic material in a direction substantially parallel to the intended direction of incident solar radiation is sufficiently thick to convert at least 90% of incident photons in the incident solar radiation to charge carriers.

4. The device of claim 3, wherein:
the width of the photovoltaic material is between 10 and 20 nm; and
the height of the photovoltaic material is at least 2 to 30 microns.

5. The device of claim 1 wherein in each photovoltaic cell:
the first electrode comprises a nanorod;
the photovoltaic material surrounds the nanorod; and
the second electrode surrounds the photovoltaic material to form a nanocoax.

6. The device of claim 5 wherein:
the nanorod comprises a nanotube, a nanofiber, or a nanowire;
each photovoltaic cell comprises the nanocoax whose axis is oriented perpendicular to a substrate of the photovoltaic device; and
the second electrode of each photovoltaic cell comprises a common electrode which fills a space between the photovoltaic cells and which electrically contacts the photovoltaic material of each photovoltaic cell.

7. The device of claim 6, wherein the device comprises a continuous photovoltaic material layer which forms the photovoltaic material in each photovoltaic cell and which is located over the substrate in a space between adjacent photovoltaic cells.

8. The device of claim 7, further comprising a conductive layer which is located between each nanorod and the photovoltaic material layer in each photovoltaic cell and which is located between the substrate and the photovoltaic material layer in a space between adjacent photovoltaic cells.

9. The device of claim 7, wherein the photovoltaic device contains the common second electrode which fills a space above the photovoltaic material layer between adjacent photovoltaic cells and which electrically contacts the photovoltaic material layer.

10. The device of claim 1, wherein the photovoltaic material comprises semiconductor nanocrystals.

11. The device of claim 1, wherein the photovoltaic material comprises bulk inorganic semiconductor material.

12. The device of claim 1, wherein the photovoltaic material comprises a polymer photoactive material, an organic molecular photoactive material or a biological photoactive material.

13. The device of claim 1, wherein a separation between first electrodes of adjacent photovoltaic cells is less than 550 nm.

14. The device of claim 13, wherein the optical skin depth of the second electrode material is less than a peak wavelength of the incident radiation.

15. The device of claim 14, wherein the second electrode comprises a metal or metal alloy which is not transmissive to solar radiation.

16. The device of claim 15, wherein the optical skin depth of the second electrode material is about 10 nm to about 20 nm.

17. The device of claim 15, wherein the device is formed on an optically transmissive substrate.

18. The device of claim 1, wherein the optical skin depth of the second electrode material is greater than a peak wavelength of the incident radiation.

19. The device of claim 18, wherein the second electrode comprises an optically transmissive, electrically conductive metal oxide.

20. The device of claim 19, wherein the optical skin depth of the second electrode material is greater than 700 nm.

21. The device of claim 19, wherein the device is formed on an optically non-transmissive substrate.

22. A method of making a photovoltaic device, comprising:
forming a plurality of first electrodes of each photovoltaic cell perpendicular to a substrate;
forming a photovoltaic material around the first electrodes; and
filling a space between photovoltaic material with a common second electrode, such that the common second electrode surrounds and electrically contacts the photovoltaic material in each photovoltaic cell;
wherein:
wherein a width of the photovoltaic material in a direction from each first electrode to the second electrode is less than about 200 nm, and a height of the photovoltaic material in a direction substantially perpendicular to the width of the photovoltaic material is at least 1 micron;
a thickness of the common second electrode of each photovoltaic cell is less than an optical skin depth of the common second electrode material; and
a separation between adjacent first electrodes is less than a peak wavelength of incident radiation.

23. The method of claim 22, wherein:
the step of forming a photovoltaic material around the first electrodes comprises forming a continuous photovoltaic material layer around the first electrodes and over the substrate; and
the step of filling a space between photovoltaic material with a common second electrode comprises forming the second electrode over first portions of the photovoltaic material layer located over the substrate and between second portions of the photovoltaic material layer surrounding the first electrodes.

24. A method of operating a photovoltaic device comprising a plurality of photovoltaic cells, wherein:
each photovoltaic cell comprises:
a first electrode;
a second electrode which is shared with at least one adjacent photovoltaic cell; and
a photovoltaic material located between and in electrical contact with the first and the second electrodes;
a thickness of the second electrodes of each photovoltaic cell is less than an optical skin depth of the second electrode material; and
a separation between first electrodes of adjacent photovoltaic cells is less than a peak wavelength of incident radiation;
the method comprising:
exposing the photovoltaic device to incident solar radiation propagating in a first direction; and
generating a current from each photovoltaic cell in response to the step of exposing;
wherein:
a width of the photovoltaic material between the first and the second electrodes in each photovoltaic cell in a second direction substantially perpendicular to the first direction is sufficiently thin to substantially prevent phonon generation during photogenerated charge carrier flight time in the photovoltaic material to at least one of the first and the second electrodes; and
a height of the photovoltaic material in a direction substantially parallel to the first direction is sufficiently thick to convert at least 90% of incident photons in the incident solar radiation to charge carriers.

25. The method of claim 24, wherein the device exhibits a parasitic optical antenna effect.

26. A photovoltaic cell, comprising:
a first electrode;
a second electrode; and
a photovoltaic material located between the first and the second electrodes, wherein the photovoltaic material comprises a semiconductor nanocrystal layer located between p-type bulk semiconductor layer and an n-type bulk semiconductor layer.

27. The cell of claim 26, wherein the nanocrystal layer comprises an intrinsic silicon nanocrystal layer having a width of about 20 to about 30 nm and the p-type and the n-type bulk semiconductor layers comprise heavily doped amorphous silicon layers each having a width of about 5 to about 10 nm.
